(19) United States
(12) Patent Application Publication
(10) Pub. No.: US 2026/0055501 A1
(43) Pub. Date: Feb. 26, 2026

(54) SEALING AIRLOCK FOR DEPOSITION CHAMBER

(71) Applicant: ArcelorMittal, Luxembourg (LU)

(72) Inventors: Vincent RUWET, Housse (BE); Didier MARNEFFE, Engis (BE); Philippe DOSSIN, Liege (BE)

(21) Appl. No.: 19/104,841

(22) PCT Filed: Aug. 31, 2023
(86) PCT No.: PCT/IB2023/058603

§ 371 Date: Feb. 19, 2025

(30) Foreign Application Priority Data
Sep. 5, 2022 (WO) PCT/IB2022/058335

(51) Int. Cl. C23C 14/56; C23C 14/16; C23C 14/24; F16J 15/16

(52) U.S. Cl. CPC C23C 14/562; C23C 14/16; C23C 14/24; F16J 15/168

(57) ABSTRACT

A sealing lock for a vacuum deposition facility of a coating on a running metal strip following a running path, including walls and at least three pairs of rolls, inside the walls, wherein each pair of rolls of the at least three pairs of rolls includes a roll with a metal surface and a roll with an elastomer surface layer, having a thickness from 3 to 30 mm, forming a gap from 1 to 11 mm, the rolls with an elastomer surface layer of two successive pairs of rolls are on opposite sides of the running path.

The present invention relates to a sealing airlock for a deposition chamber under vacuum. This sealing airlock is advantageously used as an exit airlock in a vacuum deposition facility.

### BACKGROUND

In metallurgy, the use of vapour deposition is increasingly attractive. Indeed, it allows to achieve a wider range of product, especially in terms of coating composition. Moreover, from an environmental point of view, vapour deposition generates less waste of the material to be coated.

### SUMMARY OF THE INVENTION

After undergoing thermal and mechanical treatments, a strip can be conveyed to a vapour deposition facility. The vapour deposition is performed in a vacuum chamber having pressure of the order of 10⁻⁵ mbar, or lower. The use of such a low pressure requires to isolate atmospherically the deposition chamber from the rest of the production line. Sealing locks have been developed to solve this issue.

For example, as illustrated in FIG. 1, EP 1 627 096 describes a sealing airlock 1 comprising several pairs of rolls. Each pair of roll comprises a rubber-coated roll 2 and a roll with a metal surface 3. Two successive pairs of rolls define a subchamber 4 kept at a pressure below the atmospheric one. The airtightness of each subchamber is ensured by prestressing the rubber-coated roll against the roll with the metal surface.

Unfortunately, such a sealing lock leads to the appearance of quality defect. Moreover, it is limited in strip gauges and line speed due to the mechanical and thermal resistance of the elastomer rolls.

It is an object of the present invention to provide a sealing lock for deposition chamber under vacuum overcoming the drawbacks of the state of the art. In particular, the aim is to provide a sealing lock reducing the degradation of the coating of the running metal strip due to the sealing airlock.

The present invention provides a sealing lock for a vacuum deposition facility of a coating on a running metal strip following a running path, comprising walls and at least three pairs of rolls, inside said walls, wherein
each pair of rolls of said at least three pairs of rolls,
   comprises a roll with a metal surface and a roll with an elastomer surface layer having a thickness from 3 to 30 mm, forming a gap from 1 to 11 mm, and
the rolls with an elastomer surface layer of two successive pairs of rolls are on opposite sides of said running path.

### BRIEF DESCRIPTION OF THE DRAWINGS

FIG. 1, already mentioned above, exhibits a longitudinal view of a sealing lock for a vacuum deposition in a vacuum according to the state of the art.

FIG. 2 exhibits a longitudinal view of an embodiment of a sealing lock for vacuum deposition facility according to the present invention.

FIG. 3 exhibits a longitudinal view of an embodiment of a sealing lock for vacuum deposition facility according to the present invention.

FIG. 4 exhibits a longitudinal view of a second embodiment of a sealing lock for vacuum deposition facility according to the present invention.

FIG. 5 illustrates a longitudinal view of an embodiment of depositing method according to the present invention.

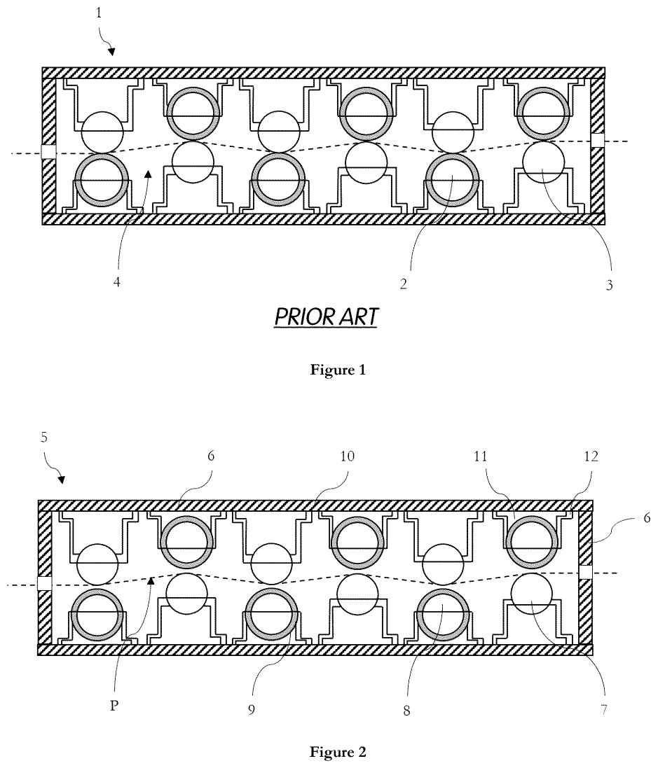

### DETAILED DESCRIPTION

It has surprisingly been observed by the inventors that an uneven strip passing through a pinching pair of rolls, as known in the state of the art, can lead to a degradation of the metallic coating. Apparently, such degradation occurs because the friction varies along the width of the strip.

With the present invention, this drawback is prevented. A gap greater than the strip thickness avoids continuously pinching the strip and thus creation of a friction differential along the strip width when it passes between a pair of rolls. This gap combined with an elastomer surface on the roll permits management of the unevenness of the strip. Indeed, where the strip is uneven due to flatness defects, the strip will briefly contact the roll but the coating of the running metal strip will not be degraded thanks to the elastomer layer.

Consequently, the combination of a gap greater than the strip thickness and the presence of a roll having an elastomer surface has a synergy effect on the preservation of the coating quality. Since the coated running metal strip is not pinched by the pair of rolls, it eliminates the friction variation along the strip width and thus preserves the coating of the running metal strip. Indeed, it suppresses the constant compression undergone by the elastomer layer imposed by the strip which also increases the elastomer layer lifetime. Furthermore, it allows processing of a thicker strip and/or at higher speed. Moreover, as the running metal strip is in contact with the roll having a metal surface but not in continuous contact with the roll having the elastomer surface, it permits in case of the strip vibration or variation in terms of thickness to allow the running metal strip to enter into contact with the roll having an elastomer layer without damaging the coating of said strip.

As illustrated in FIG. 2, the walls 6 of the sealing lock define the sealing lock chamber 10. The sealing lock 5 walls can be defined as lateral, upper and lower walls.

Each roll can be located in a cradle 11 fastened to the lower walls or the upper walls facing the roll. This arrangement allows to minimise leakage. Preferably, the lower and upper walls are removable covers.

Roll bearings 12 can be detached and are fastened to the upper and lower walls (e.g., the covers). It permits to ensure the maintenance of the chamber and an easy access to the rolls.

Moreover, the rolls are held on the side of the cover that faces them in a cradle. This arrangement allows to minimise leakage.

The sealing lock 5 comprises at least three pairs of rolls. Preferably, the sealing lock comprises at least five pairs of rolls. Preferably, the sealing lock comprises at most nine pairs of rolls. In the embodiment represented on FIG. 2, the chamber comprises six pairs of rolls between which a metal strip is able to pass.

The rolls are at least as wide as the running metallic width.

A pair of rolls comprises a roll with a metal surface 7 and a roll with an elastomer surface layer 8. The roll with an elastomer surface layer is a roll having on its periphery a layer of elastomer 9 having a thickness from 3 to 30 mm. Such an elastomer layer thickness range is advantageous. Indeed, an elastomer layer thickness of at least 3 mm allows to obtain a lifespan sufficient for industrial purposes. An elastomer layer thickness of maximum 30 mm allows to keep the elastomer layer sufficiently cool. Indeed, if the elastomer layer thickness is greater than 30 mm, removing heat by the rolls become too hard.

### Preferably, the Roll With a Metal Surface Has a Steel Surface.

Preferably, said elastomer layer is from 5 to 15 mm thick. Even more preferably, said elastomer layer is from 5 to 10 mm thick Preferably, said elastomer layer is a made of vulcanised elastomer. Even more preferably the elastomer is made of fluorocarbon rubber as defined by the ASTM International standard D1418 in the “FKM” category. Even more preferably, the elastomer is made of Hydrongenated Acrylonitrile Butadiene as defined by the ASTM International standard D1418 in the “HNBR”category.

A pair of rolls defines a gap between said two rolls. Preferably, the pair of rolls is configured such that the gap between two rolls can be from 1 to 11 mm. It permits to have a gap from 0.8 to 3 mm between the roll with an elastomer surface and a running metal strip having a thickness from 0.2 to 8 mm.

Even more preferably, the pair of rolls is configured such that the gap between two rolls can be from 1 to 5 mm. This is particularly advantageous for thin strip having a thickness of maximum 4 mm.

Advantageously, said rolls with an elastomer surface layer comprises a cooling system able to cool the elastomer surface layer. Preferably, cooling system comprises a ferrule in which a coolant is passed. Preferably, said elastomer surface layer contacts said ferrule.

The pairs of rolls are arranged such that the rolls with an elastomer surface of two successive pairs of rolls are on opposite sides of the running path P. For example, as illustrated in FIG. 2, the first, third and fifth rolls (from left to right) on the upper side of the running path P have a metal surface while the second, fourth and sixth rolls have an elastomer surface.

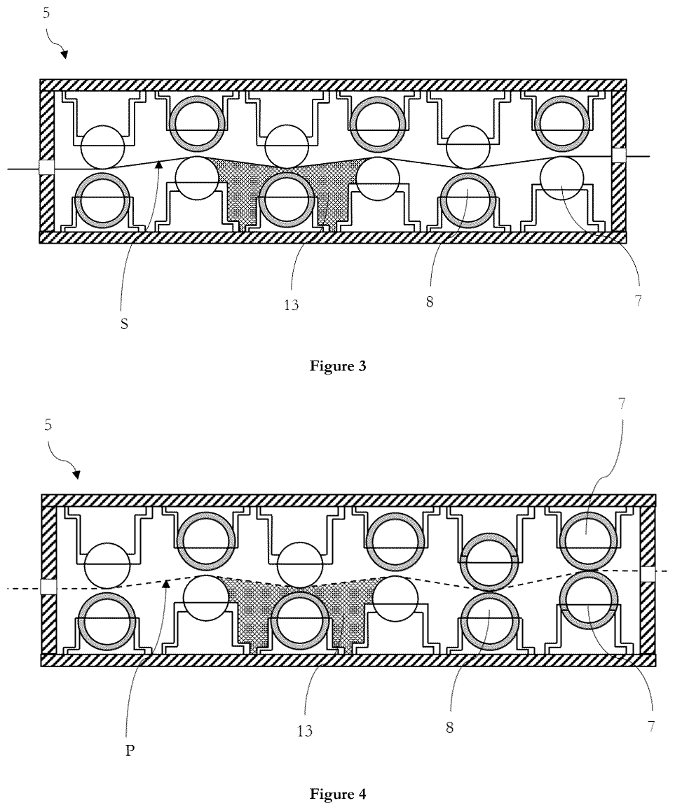

The pairs of rolls are arranged such that two successive metal rolls, the strip S (e.g. the running path of the strip) and the walls of the sealing lock defines sub-chambers 13. A subchamber 13 is represented by a hashed area in FIG. 3. Each of the sub-chambers is connected to at least a pumping system. As illustrated in FIG. 2, the direction of the running path P is changed at every metallic roll.

Preferably, a sub-chamber is defined by two successive metal rolls, said running path P and the walls of said sealing lock.

Consequently, the disposition of elastomeric rolls, and rolls having metal surface permits to defines sub chambers as illustrated in FIG. 3. Indeed, if all the rolls having the metal surface, with which the running metal strip is in contact, were on the same side of the running metal strip, it would not permit to define sub-chambers and thus not permit to create an airlock.

In operation, the pressure of the successive sub-chambers decreases towards the deposition chamber, e.g. from the entry to the exit for an entry sealing lock. In the case of an exit lock, the reverse situation occurs.

Preferably, the pressure of said at least one sub-chambers decreases towards the deposition chamber

The pressure of the successive sub-chambers is managed by a pumping system. Such a pumping system is well known by the person skilled in the art. For example, the pumping system can work in cascade from the sub-chambers closest to the deposition chamber toward the opposite sub-chamber. It permits to handle the pressure difference between the sub-chambers. The pumping system can comprise several types of pumps such as the liquid ring pump, roots pump and turbomolecular pump.

Optionally, the sealing lock includes at least one additional pair of rolls comprising two rolls with an elastomer surface and located at the exit of said sealing lock, said lock forming a gap from 2 to 8 mm. Even more preferably, said at least one pair of rolls closest to an exit of said sealing lock defines a gap able to pinch said running metal strip passing between. Such an embodiment is illustrated in FIG. 4 wherein the sixth pair of rolls comprise two rolls with an elastomer surface.

It has surprisingly been found that coating quality issue is not only due to the pinching of the strip by the rolls but is also dependant of the strip temperature, (e.g. the deposited coating temperature). After being coated, the strip temperature decreases in the sealing lock which allows to use pair of pinching rolls on the exit side of the sealing lock.

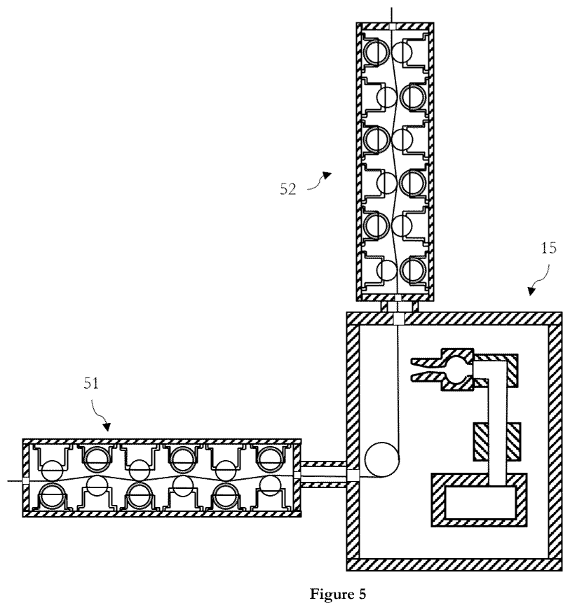

The present invention also relates to a vacuum deposition facility comprising a vacuum deposition chamber connected to one entry sealing lock 51 or one exit sealing lock 52 as previously described and illustrated in FIG. 5.

Preferably, the vacuum deposition facility comprising a vacuum deposition chamber connected to one entry sealing lock and one exit sealing lock as previously described.

Preferably, said vacuum deposition facility is able to coat a running metallic substrate by propelling at least one metallic vapor at a supersonic speed towards said running strip.

The invention, as illustrated in FIG. 5 also relates to a method for continuously depositing on a running metal strip, coatings from at least one metal inside a vacuum deposition facility comprising an exit sealing lock 52, said method comprising the successive steps of:
depositing at least one metallic coating on said running strip in said vacuum deposition chamber, and
passing said running strip through said exit sealing lock 52 such that when said strip passes between a pair of rolls, comprising a metallic roll and an elastomer roll, said running metal strip is in contact with said metallic rolls and that the gap between two rolls of said pair is from 0.8 to 3 mm greater than the running strip thickness.

As illustrated in FIG. 5, the running metal strip enters the sealing lock 51 from one side (the left side on FIG. 5) and comes out of it on another side (the right on FIG. 5), preferably the opposite side in the sense that the strip path is essentially a straight line.

In the first step, a coating layer of a at least one metal is deposited on at least one side of the running metal strip in vacuum deposition chamber 15.

Preferably, said metallic coating deposition is done by propelling at least one metallic vapor at a supersonic speed towards said running strip.

In the second step, the running metal strip passes through the sealing lock 52. As illustrated in FIG. 5, the strip runs between each pair of rolls. The strip is in contact and is pressed by each of the metallic rolls such as to form a seal between the metal surface of the rolls and the strip. The running path of the strip is deflected by each of the metallic rolls. A gap from 0.8 to 3 mm is formed between the running metal strip and the roll with an elastomer layer such that the running metal strip is not continuously pinched by a pair of rolls comprising a roll with a metal surface and a roll with an elastomer layer. However, as the strip has sometimes flatness defect, the gap may momentarily be smaller, and the strip may even contact the elastomer layer for a brief moment.

Preferably, the rolls with an elastomer surface layer, of a pair with a metal surface are in rotation. This rotation avoids local overheating due to the radiation of the running metal strip and helps extending the roll lifetime.

Even more preferably, in a pair of rolls, the direction of rotation of the roll with an elastomer surface layer is the opposite of the direction of rotation of the roll with a metal surface. Such a direction of rotation lowers the coating degradation. For example, in FIG. 3, the movement of direction of the strip S is from left to right and the direction of rotation of the rolls with an elastomer surface layer of the first, third and fifth pairs of rolls is clockwise while the direction of rotation of the rolls with a metal surface is anticlockwise.

Preferably, when using a sealing lock including at least one additional pair of rolls comprising two rolls with an elastomer surface and located at the exit of said sealing lock, said strip is pinched between said additional pair of elastomer rolls having a gap between said elastomer rolls.

The running strip has a thickness, generally from 0.2 to 8 mm. However, sometimes said strip has flatness defect.

Preferably, said running strip has a thickness from 0.2 to 4 mm.

1-12. (canceled)

13. A sealing lock for a vacuum deposition facility of a coating on a running metal strip following a running path, the sealing lock comprising:
walls; and
at least three pairs of rolls, the at least three pairs of rolls being configured inside the walls,
wherein each pair of rolls of the at least three pairs of rolls comprise:
a roll with a metal surface; and
a roll with an elastomer surface layer having a thickness of 3 to 30 mm and forming a gap of 1 to 11 mm with the roll with the metal surface,
wherein the rolls with the elastomer surface layer of two successive pairs of rolls are on opposite sides of the running path.

14. The sealing lock according to claim 13 wherein the at least three pairs of rolls include at least five pairs of rolls.

15. The sealing lock according to claim 13 wherein the thickness is from 5 to 15 mm.

16. The sealing lock according to claim 13 including at least one additional pair of rolls, the additional pair of rolls including two rolls with an elastomer surface and located at the exit of the sealing lock, the additional pair of rolls forming a gap from 0.2 to 8 mm.

17. The sealing lock according to claim 13 wherein a sub-chamber is defined by two successive metal rolls, the running path and the walls of the sealing lock.

18. A vacuum deposition facility comprising:
the sealing lock as recited in claim 13 and
a vacuum deposition chamber connected to the sealing lock.

19. The vacuum deposition facility as recited in claim 18 wherein the sealing lock is an exit sealing lock.

20. A method for continuously depositing on a running metal strip, coatings from at least one metal inside the vacuum deposition facility as recited in claim 19, the method comprising the successive steps of:
depositing at least one metallic coating on the running strip in the vacuum deposition chamber; and
passing the running strip through the exit sealing lock such that the strip passes between a pair of rolls, the pair of rolls comprising a metallic roll and an elastomer roll, the running metal strip is in contact with the metallic rolls and that the gap between two rolls of the pair is from 0.8 to 3 mm greater than the running strip thickness.

21. The method according to claim 20 wherein the metallic coating deposition is done by propelling at least one metallic vapor at a supersonic speed towards the running strip.

22. The method according to claim 20 wherein the exit lock includes at least one additional pair of rolls, the additional pair of rolls including two rolls with an elastomer surface and located at the exit of the sealing lock, the additional pair of rolls forming a gap from 0.2 to 8 mm and the strip is pinched between the additional pair of elastomer rolls.

23. The method according to claim 20 wherein the pressure of the at least one sub-chambers decreases towards the deposition chamber.

24. The method according to claim 20 wherein the rolls with an elastomer surface layer of a pair with a metal surface are in rotation.

25. The method according to claim 20 wherein, the direction of rotation of the roll with an elastomer surface layer is the opposite of the direction of rotation of the roll with a metal surface.
